(19) United States
(12) Patent Application Publication
(10) Pub. No.: US 2004/0221678 A1
(43) Pub. Date: Nov. 11, 2004

(54) Illuminated decorative shifter boot

(76) Inventors: Troy Galway, Brampton (CA); Irma Cicconetti, Brampton (CA)

Correspondence Address: Elias C. Borges, Suite 406, 1 Eva Road, Toronto, ON, M9C 4Z5, CA

(21) Appl. No.: 10/840,260

(22) Filed: May 7, 2004

Related U.S. Application Data
(60) Provisional application No. 60/468,940, filed on May 9, 2003.

(51) Int. Cl. G03F 9/00

(52) U.S. Cl. 74/523

(57) ABSTRACT

The present invention is a luminous gear shifter assembly for a car. The assembly consists of a shifter housing having a cavity and a rim circumferentially surrounding the cavity. A light source is contained inside the cavity and the cavity is covered by a shifter boot having a peripheral edge and a centrally disposed shifter aperture, the peripheral edge of the shifter boot being mounted to the rim of the shifter boot. The assembly further includes a shifter lever having an end, said end passing through the shifter cavity and a shifter knob mounted to the end of the shifter lever. The shifter boot is made of a translucent material having light pipe properties.

### CROSS REFERENCE TO RELATED APPLICATION

The present application claims priority from U.S. Provisional application serial No. 60/468,940 which was filed on May 9, 2003 the entirety of which is incorporated herein by reference.

### FIELD OF THE INVENTION

The invention relates generally to gear shift levers for use with automobiles.

### BACKGROUND OF THE INVENTION

Automobiles having standard transmissions generally have a gear shift lever located in the drivers compartment. The gear shift lever is usually mounted in a center console next to the drivers seat. The gear shift lever comprises an elongated rod which has a lower end which is coupled to the automobiles transmission and an upper end which is provided with a shifter knob. The lower end is usually covered by a flexible rubber boot. To enhance the visual appeal of the gear shifter assembly, the shifter knob may be made of decorative wood or brightly colored plastic or metal.

### SUMMARY OF THE INVENTION

The present invention is a luminous shifter boot assembly for an automobile gear shifter. The shifter boot assembly consists of a shifter housing, a light source contained in the shifter housing, and a shifter boot mounted to the shifter housing. The shifter boot is made of a flexible and substantially translucent material having light pipe properties.

With the foregoing in view, and other advantages as will become apparent to those skilled in the art to which this invention relates as this specification proceeds, the invention is herein described by reference to the accompanying drawings forming a part hereof, which includes a description of the preferred typical embodiment of the principles of the present invention.

### DESCRIPTION OF THE DRAWINGS

FIG. 1. is a perspective view of a gear shift assembly made in accordance with the present invention showing the decorative boot.

FIG. 2. is a perspective view of the gear shift assembly shown in FIG. 1 with the decorative boot removed.

In the drawings like characters of reference indicate corresponding parts in the different figures.

### DETAILED DESCRIPTION OF THE INVENTION

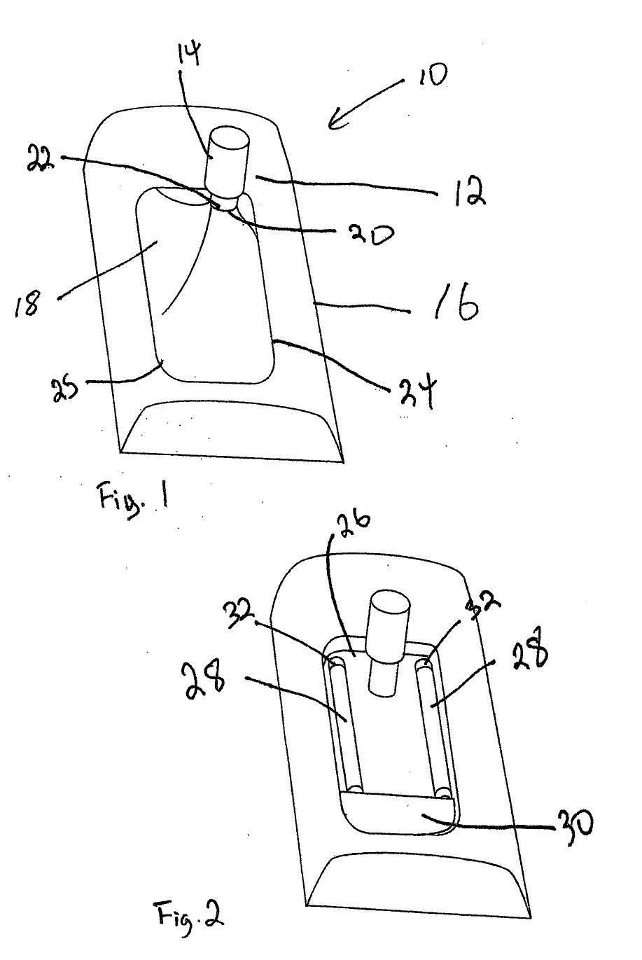

Referring to FIGS. 1 and 2, the present invention consists of a gear shifter and brake lever assembly, shown generally as item 10 having a lever 12 having knob 14 mounted to a center console 16 and to a flexible translucent boot 18. Lever 12 may be any hand operated lever normally found in a car such as a manual or automatic gear shift lever or a parking brake lever; however, it is anticipated that in most applications, lever 12 will be a gear shift lever for a car having a manual transmission. Translucent boot 18 is made of a flexible and translucent material such as translucent vinyl coated nylon or any other durable material which will permit light to pass through. Translucent boot 18 has an aperture 20 which is dimensioned to permit shaft 22 of gear shift lever 12 to pass through. Boot 18 has a peripheral edge 25 which is mounted to ridge 24 of center console 16 by means known generally in the art, such as retaining clips or mounting bolts (not shown).

Center console 16 has a central cavity 26 which is covered by boot 16. Mounted within cavity 26 is one or more neon lights 28 which are operatively coupled to electrical connectors 30 and 32. Electrical connectors 30 and 32 are operatively coupled to the automobiles electrical system such that the electrical connectors supply neon lights 28 with electrical power sufficient to make the neon lights glow. A ballast control circuit (not shown) may have to be provided in order to adjust the voltage of the electrical power supplied to neon lights 28. Suitable ballast control circuits are generally available through the marketplace. When the car is started, electrical power is supplied to neon lights 28 and they glow brightly. Since boot 18 covers neon lights 28, and since boot 18 is translucent, the boot itself glows. Preferably, boot 18 is made of a material which permits the light to be partially transmitted through the boot in a “light pipe” effect. This permits the entire boot to glow and diffuse the light of neon lights 28 to form a glowing “pool of light” upon which the gear shift knob floats. Also, boot 18 may be made of a material which is also flourescent. A flourescent boot with “light pipe” properties would glow in a very uniform fashion, especially if lights 28 are neon lights. Neon lights often produce shorter wavelength light which would cause the boot to glow flourescently.

In order to achieve the desired “pool of light” effect, the material forming boot 18 must be both light transmitting and translucent. Simply being translucent is not sufficient, for translucent materials, for example cotton fabric, cannot transmit light in a “light pipe” fashion. If boot 18 were made of a translucent material which does not transmit light, then neon lights 28 would be clearly visible underneath the boot and those portions of the boot which do not directly overlap the neon lights would not glow. A light transmitting material has the ability to transmit light through the material so that the entire boot glows. Several plastic materials have the ability to transmit light in a light pipe fashion, so plastic sheets or plastic coated fabrics may be suitable. Transparent materials are to be avoided because transparent materials would not sufficiently diffuse the light generated from neon lights 28 to create the desired “pool of light” effect. It has been discovered that translucent PVC is a suitable material for use in making the translucent boot. Preferably, for additional visual effectiveness, the translucent material should have flourescent properties. A boot made of a flexible light transmitting, translucent and flourescent material will glow very evenly creating an impressive “pool of light” display.

A specific embodiment of the present invention has been disclosed; however, several variations of the disclosed embodiment could be envisioned as within the scope of this invention. It is to be understood that the present invention is not limited to the embodiments described above, but encompasses any and all embodiments within the scope of the following claims.

We claim:

1. A shifter boot assembly for an automobile gear shifter comprising:
a) a shifter housing,
b) a light source contained in the shifter housing, and
c) a shifter boot mounted to the shifter housing, the shifter boot having a shifter aperture, the shifter boot being made of a flexible and substantially translucent material.

2. The shifter boot assembly of claim 1 wherein the shifter boot is made of a material having light pipe properties.

3. The shifter boot assembly of claim 2 wherein the shifter boot is made from translucent vinyl.

4. The shifter boot assembly of claim 1 further comprising a gear shifter, the gear shifter passing through the shifter aperture, the gear shifter having a shifter knob mounted thereto.

5. The shifter boot assembly of claim 2 wherein the material forming the shifter boot is flourescent and wherein the light source is a neon light.

6. A gear shifter for a car comprising:
a) a shifter housing having a cavity and a rim circumferentially surrounding the cavity;
b) a light source contained inside the cavity;
c) a shifter boot having a peripheral edge and a centrally disposed shifter aperture, the peripheral edge of the shifter boot being mounted to the rim of the housing;
d) a shifter lever having an end, said end passing through the shifter cavity;
e) a shifter knob mounted to the end of the shifter lever, and
f) the shifter boot being made of a translucent material having light pipe properties.

7. The shifter boot assembly of claim 6 wherein the material forming the shifter boot is made of translucent vinyl.

8. The shifter boot assembly of claim 7 wherein the material forming the shifter boot is flourescent and wherein the light source is a neon light.

9. A lever assembly for a car comprising:
a) a lever housing having a cavity and a rim circumferentially surrounding the cavity;
b) a light source contained inside the cavity;
c) a flexible boot having a peripheral edge and a centrally disposed lever aperture, the peripheral edge of the flexible boot being mounted to the rim of the housing;
d) a lever having an end, said end passing through the lever cavity;
e) a lever knob mounted to the end of the lever, and
f) the flexible boot being made of a translucent material having light pipe properties.

10. The lever assembly of claim 9 wherein the material forming the flexible boot is made of translucent vinyl.

11. The lever assembly of claim 10 wherein the material forming the flexible boot is flourescent and wherein the light source is a neon light.
